(19) United States
(12) Patent Application Publication
(10) Pub. No.: US 2025/0227875 A1
(43) Pub. Date: Jul. 10, 2025

(54) MAGNETICALLY COUPLED FAN ASSEMBLY

(71) Applicant: XFX Creation Inc., Hong Kong (CN)

(72) Inventor: Chia-Hung LEE, New Taipei City (TW)

(21) Appl. No.: 18/407,301

(22) Filed: Jan. 8, 2024

(51) Int. Cl. H05K 7/20; F04D 25/06; F04D 25/08; F04D 29/64; G06F 1/20

(52) U.S. Cl. CPC H05K 7/20172; F04D 25/06; F04D 25/08; F04D 29/646; G06F 1/20; H05K 7/20209

(57) ABSTRACT

A fan assembly may include a fan blade assembly and a base assembly. The fan blade assembly may include a plurality of fan blades, a first magnetic element, and a connector. The base assembly may include a printed circuit board and a second magnetic element. The printed circuit board may include at least one continuous circular contact ring on a first face of the printed circuit board. The first magnetic element and the second magnetic element may be configured to be removably coupled to one another. The connector may be in contact with the at least one continuous circular contact ring of the printed circuit board when the first magnetic element and second magnetic element are removably coupled. The fan blade assembly may be configured to selectively rotate when the first magnetic element and the second magnetic element are removably coupled to one another.

### BACKGROUND

### Technical Field

The present disclosure is related to fans, and more particularly, fans having removable blade assemblies.

### Description of the Related Art

Computers often include graphics cards to generate images which may then be displayed on a monitor. When in operation, graphics cards can generate heat, which could potentially damage the graphics cards. To cool graphics cards and reduce the potentially damaging heat, fans will commonly be included in such computers to cool the graphics cards by circulating air over the graphics cards. Due to the movement of air through the fans, dust can accumulate on the fan blades, which may reduce the effectiveness of such fans and affect performance of the computer components. To assist in cleaning such blades, some fans allow the blades to be removed. However, removal blades typically require a fastener, such as a screw or a retaining clip, to couple the blades of the fan to a base of the fan.

### BRIEF SUMMARY

Embodiments described herein provide fan assemblies including removable fan blade assemblies for cooling computer components. The fan assemblies including removable fan blade assemblies may allow simple removal and connection of the fan blade assembly. The simple removal and connection of the fan blade assembly facilitates cleaning of the fan assembly. Moreover, the simple removal and connection of the fan blade assembly allows users to regularly and simply change the fan blade assemblies used on a computer.

In one embodiment, a fan assembly includes a fan blade assembly and a base assembly. The fan blade assembly may include a plurality of fan blades, a first magnetic element, and a connector. The plurality of fan blades may extend from a blade center. The base assembly may include a printed circuit board and a second magnetic element. The printed circuit board may include at least one continuous circular contact ring on a first face of the printed circuit board. The first magnetic element and the second magnetic element may each be configured to be removably coupled to one another. The connector may be in contact with the at least one continuous circular contact ring of the printed circuit board when the first magnetic element and second magnetic element are removably coupled. The fan blade assembly may be configured to selectively rotate about the blade center when the first magnetic element and the second magnetic element are removably coupled to one another. The base assembly may be configured to remain rotatably stationary when the fan blade assembly is rotating.

In some embodiments, the connector may be in contact with the at least one continuous circular contact ring of the printed circuit board when the fan blade assembly is in any rotational position relative to the base assembly.

In some embodiments, the first magnetic element and the second magnetic element may each be configured to remain rotatably coupled as the fan blade assembly rotates relative to the base assembly.

In some embodiments, the first magnetic element may be configured to be decoupled from the second magnetic element by a applying a force to the fan blade assembly in a direction away from the second magnetic element.

In some embodiments, the first magnetic element may be concentric with the plurality of fan blades. The second magnetic element may be concentric with the at least one continuous circular contact ring.

In some embodiments, the connector may include one or more pins. Each pin of the one or more pins may be in contact with a respective continuous circular contact ring of the one or more continuous circular contact rings when the first magnetic element is removably coupled to the second magnetic element.

In some embodiments, the fan blade assembly may further include a DC motor configured to rotate the plurality of fan blades about the blade center.

In some embodiments, the DC motor may be controlled by a computer electronically coupled to the fan assembly.

In some embodiments, the fan blade assembly may be configured to force air over a graphics card of a computer.

In another embodiment, a computer component cooling assembly includes a fan blade assembly and a computer chassis. The fan blade assembly may include a plurality of fan blades, a first magnetic element, and a connector. The plurality of fan blades may extend from a blade center. The computer chassis may include a fan attachment unit. The fan attachment unit may include a printed circuit board and a second magnetic element. The printed circuit board may include at least one continuous circular contact ring on a first face of the printed circuit board. The first magnetic element and the second magnetic element may each be configured to be removably coupled to one another. The connector may be in contact with the at least one continuous circular contact ring of the printed circuit board when the first magnetic element and second magnetic element are removably coupled. The fan blade assembly may be configured to selectively rotate about the blade center when the first magnetic element and the second magnetic element are removably coupled to one another. The fan attachment unit may be configured to remain rotatably stationary when the fan blade assembly is rotating.

In some embodiments, the connector may be in contact with the at least one continuous circular contact ring of the printed circuit board when the fan blade assembly is in any rotational position relative to the fan attachment unit.

In some embodiments, the first magnetic element and the second magnetic element may each be configured to remain rotatably coupled as the fan blade assembly rotates relative to the fan attachment unit.

In some embodiments, the first magnetic element may be configured to be decoupled from the second magnetic element by a applying a force to the fan blade assembly in a direction away from the second magnetic element.

In some embodiments, the first magnetic element may be concentric with the plurality of fan blades. The second magnetic element may be concentric with the at least one continuous circular contact ring.

In some embodiments, the connector may include one or more pins. Each pin of the one or more pins may be in contact with a respective continuous circular contact ring of the one or more continuous circular contact rings when the first magnetic element is removably coupled to the second magnetic element.

In some embodiments, the fan blade assembly may further include a DC motor configured to rotate the plurality of fan blades about the blade center.

In some embodiments, the DC motor may be controlled by a computer housed in the computer chassis.

In some embodiments, the fan blade assembly may be configured to force air over a component of a computer housed in the computer chassis.

### BRIEF DESCRIPTION OF THE SEVERAL VIEWS OF THE DRAWINGS

FIG. 1 is a bottom perspective view of a first embodiment of a magnetically coupled fan assembly.

FIG. 2 is a bottom plan view of a fan blade assembly of the magnetically coupled fan assembly of FIG. 1.

FIG. 3 is a top plan view of a base assembly of the magnetically coupled fan assembly of FIG. 1.

FIG. 4 is a diametric cross-sectional side view of fan blade assembly removably coupled to the base assembly of the fan assembly of FIG. 1.

FIG. 5 is a bottom perspective view of a second embodiment of a magnetically coupled fan assembly.

FIG. 6 is a side view of the magnetically coupled fan assembly of FIG. 5.

### DETAILED DESCRIPTION

In the following description, certain specific details are set forth in order to provide a thorough understanding of various disclosed embodiments. However, one skilled in the relevant art will recognize that embodiments may be practiced without one or more of these specific details. In other instances, well-known structures and manufacturing techniques associated with fans may not be shown or described in detail to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is as “including, but not limited to.”

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

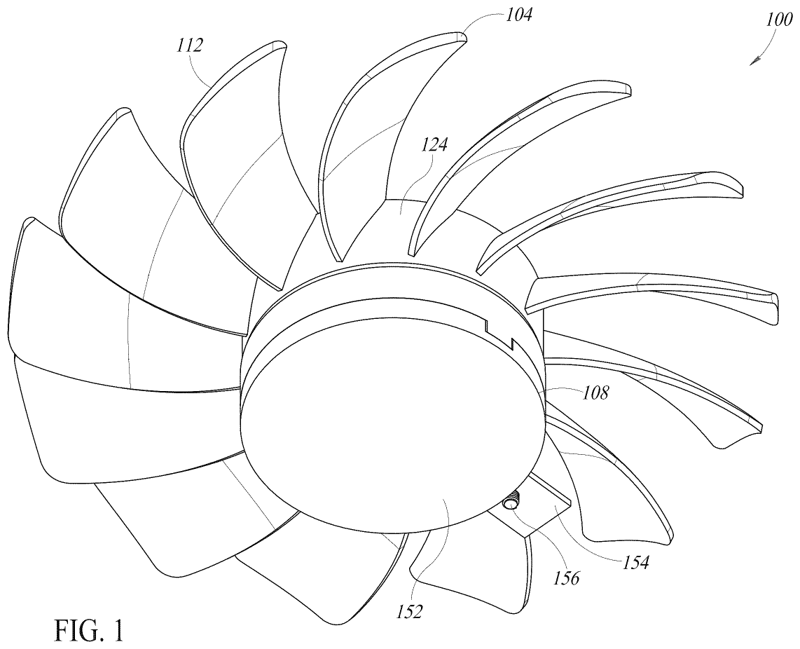

FIG. 1 shows a magnetically coupled fan assembly 100 for cooling graphics cards or other computer components. The magnetically coupled fan assembly 100 includes a fan blade assembly 104 and a base assembly 108. The fan blade assembly 104 may be removably coupled to the base assembly 108. The fan blade assembly 104 and the base assembly 108 may be configured to be removably coupled without the need for a fastener, such as a screw or a retaining clip. Fan assemblies including a screw or retaining clip require an act by a user which amounts to more than simple pulling in order to remove a fan blade assembly from a corresponding base assembly. Removing the need for a fastener may simplify cleaning of the fan assembly.

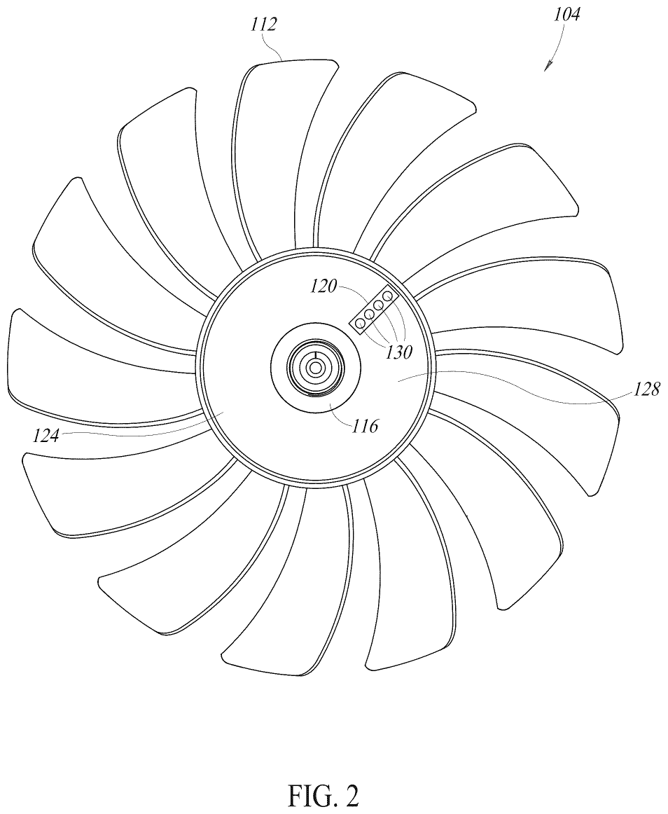

FIG. 2 shows a bottom view of the fan blade assembly 104. The fan blade assembly 104 may include a plurality of fan blades 112, a first magnetic element 116, and a connector 120. Each fan blade of the plurality of fan blades 112 may extend generally radially outward from a blade base 124. The blade base 124 may be configured to rotate. Rotation of the blade base 124 causes each fan blade of the plurality of fan blades 112 to rotate about the blade base 124. Each fan blade of the plurality of fan blades 112 may be configured to force air in a desired direction when the plurality of fan blades 112 is rotating. Air forced in a desired direction by the rotating plurality of fan blades 112 may be utilized to cool a graphics card, or other computer components, via convection.

The connector 120 may be disposed on a first face 128 of the blade base 124. The connector 120 may include a plurality of pins 130. In some embodiments, the connector 120 may be a 4-pin connector. In embodiments in which the connector includes a plurality of pins 130, each pin of the plurality of pins 130 may be adjacent to one another. In some embodiments, the pins may be aligned radially outward from the blade base 124. In some embodiments, each pin of the plurality of pins 130 may be aligned radially outward in a row, such as in the embodiment shown in FIG. 2. In some embodiments, each pin of the plurality of pins 130 may be radially, outwardly offset from one another. In some examples, each pin of the plurality of pins 130 may be configured to transmit a different signal, as with traditional pin connectors. For example, in some embodiments including a 4-pin connector, a first pin my provide power to a motor (described further below) of the fan assembly 100, a second pin may be ground, a third pin may transmit a tachnometric signal, and a fourth pin may provide a pulse width modulation signal to the motor.

The first magnetic element 116 may be disposed on the first face 128 of the blade base 124. In some embodiments, the first magnetic element 116 may be circular. In some embodiments, the first magnetic element 116 may be disposed in a center position of the blade base 124, such that the first magnetic element 116 is positioned radially inward from the connector 120. In some embodiments, the first magnetic element 116 may be concentric with the plurality of fan blades 112.

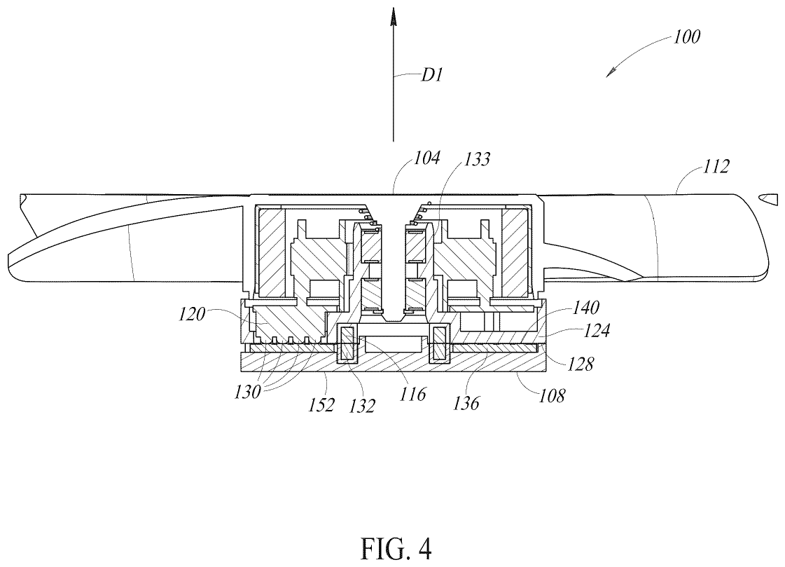

The fan blade assembly 104 may also include a motor 133 (FIG. 4) configured to selectively rotate the plurality of fan blades 112 about the blade base 124. The motor 133 may be disposed within the blade base 124. In some embodiments, the motor 133 may be a DC motor. In some embodiments, the motor 13 may be a brushless DC motor. In some embodiments, the motor 133 may be a 12-volt DC motor. The motor 133 may be in electrical communication with the connector 120, such that the motor 133 may receive operation signals and power from the connector 120.

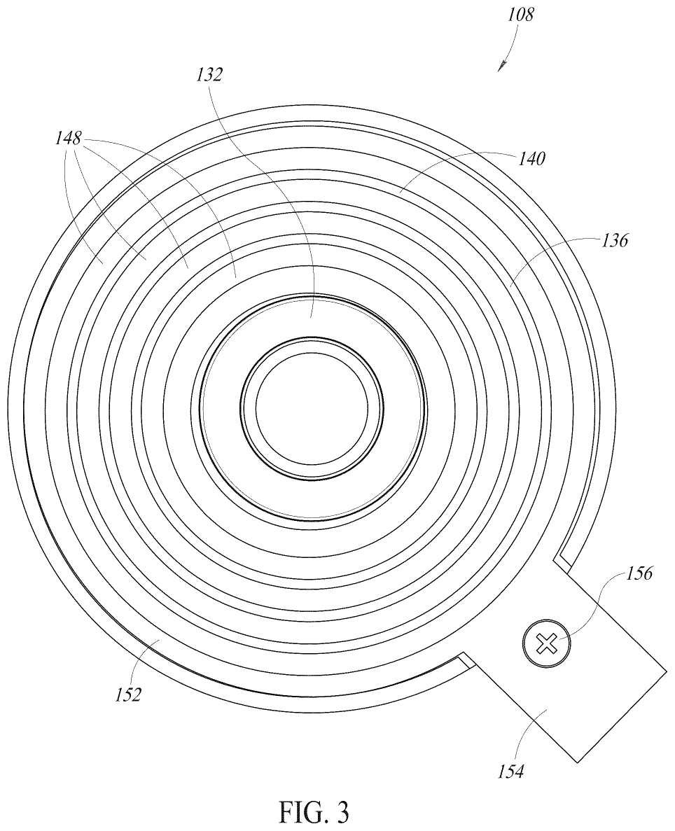

FIG. 3 shows a top view of the base assembly 108. The base assembly 108 may include a second magnetic element 132 and a printed circuit board 136. The base assembly 108 may be fixed to computer chassis, a fan attachment, or the like. The second magnetic element 132 may be disposed on a first face 140 of the printed circuit board 136. In some embodiments, the second magnetic element 132 may be circular. In some embodiments, the second magnetic element 132 may be disposed in a center position of the printed circuit board 136. The second magnetic element 132 may be sized and shaped equivalent to the first magnetic element 116. The second magnetic element 132 may be configured to removably couple to the first magnetic element 116. When the first magnetic element 116 and the second magnetic element 132 are coupled to one another, as is shown in FIG. 4, the first magnetic element 116 may rotate relative to the second magnetic element 132 while maintaining coupling with the second magnetic element 132.

The first magnetic element 116 and the second magnetic element 132 may each be configured such that coupling between the first magnetic element 116 and the second magnetic element 132 is of sufficient strength to guarantee coupling of the fan blade assembly 104 and the base assembly 108 during normal operation of the fan. Additionally, the first magnetic element 116 and the second magnetic element 132 may each be configured such that the first magnetic element 116 and the second magnetic element 132 may be decoupled by a user pulling the fan blade assembly 104 away from the base assembly 108. In other words, the first magnetic element 116 may be configured to be decoupled from the second magnetic element 132 by applying a force to the fan blade assembly 104 in a direction DI (FIG. 4) away from the second magnetic element 132. Such a configuration allows the fan assembly 100 to be operable, but also allows easy removal of the fan blade assembly 104 by a user. Such easy removal allows a user to remove the fan blade assembly 104, clean any dust from the graphics card and/or fan blades which may have accumulated, and replace the fan blade assembly 104 without the need for manual insertion or placing of any coupling hardware. Additionally, such removal allows for simple changing of the fan blade assembly 104, in the event a user wishes to change a characteristic of the aesthetic appearance of the fan blade assembly 104 (e.g., different color fan blades, different shape of fan blades).

The printed circuit board 136 may be circular shaped, as shown in FIG. 3. The first face 140 of the printed circuit board 136 may include at least one continuous circular contact ring 148. In some embodiments, the first face 140 of the printed circuit board 136 may include four continuous circular contact rings 148, arranged such that each consecutive continuous circular contact ring 148 is spaced radially outward from a previous continuous circular contact ring 148. In other words, each continuous circular contact ring 148 may be concentric and each continuous circular contact ring of the continuous circular contact rings 148 may be spaced at a different radius than the other continuous circular contact rings 148. The number of continuous circular contact rings 148 present on the first face 140 of the printed circuit board 136 may be identical to the number of pins of the of the connector 120. For example, in embodiments in which the connector 120 is a 4-pin connector, the printed circuit board 136 may include four continuous circular contact rings 148. In such embodiments, each continuous circular contact ring 148 may align with a pin of the connector 120, such that when the fan blade assembly 104 is coupled to the base assembly 108, each pin of the connector 120 remains in contact with a continuous circular contact ring 148 regardless of the rotational position of the fan blade assembly 104. Such contact can be seen in FIG. 4.

The second magnetic element 132 may be disposed on the printed circuit board 136. The second magnetic element 132 may be disposed on the first face 140 of the printed circuit board 136. The second magnetic element 132 may be disposed in a center position of the first face 140 of the printed circuit board. In some embodiments, the second magnetic element 132 may be concentric with the at least one continuous circular contact ring 148.

The printed circuit board 136 may be disposed on a support structure 152, which may be configured to support the printed circuit board 136 and to hold the printed circuit board 136 stationary. The support structure 152 may be coupled to a computer chassis (not shown) by the use of a fastener 156. The support structure 152 may include a fastener tab 154, which may extend from the support structure 152. The fastener tab 152 may be configured to enable the fastener 156 to extend therethrough when coupling the support structure 152 to the computer chassis.

In order to assemble the fan assembly 100, the fan blade assembly 104 may be placed in a position adjacent to the base assembly 108, such that the first magnetic element 116 and the second magnetic element 132 are drawn to one another. When the base assembly 108 is fixed, the fan blade assembly 104 will be drawn toward the base assembly 108 through the magnetic force of the first and second magnetic elements 116, 132.

When the fan blade assembly 104 is coupled to the base assembly 108 (i.e., the first magnetic element 116 is coupled to the second magnetic element 132), the printed circuit board 136 may transmit control signals through the continuous circular contact rings 148 to the connector 120. Such signals may control operation of a motor configured to rotate the plurality of fan blades 112 of the fan blade assembly 104. In some embodiments, the control signals may provide direction to the motor 133 to selectively operate. In some embodiments, the control signals may control the speed at which the plurality of fan blades 112 are rotated. For example, a rotation speed of the plurality of fan blades 112 may be determined by pulse-width modulation. Such control signals may be directed from a controller (not shown). The controller may be embedded within an attached computer. The attached computer may utilize the graphics card which is configured to be cooled by the fan assembly 100.

When the plurality of fan blades 112 are rotating, the base assembly 108 is configured to remain stationary. As the plurality of fan blades 112 rotate, the connector 120 will maintain contact with at least one continuous circular contact ring 148, regardless of the rotational position of the fan blade assembly 104.

In order to remove the fan blade assembly 104 from the base assembly 108, a force may be applied to the fan blade assembly 104 in direction DI, which is away from the base assembly 108. For example, this may be accomplished by a user of the fan assembly 100 pulling on the fan blade assembly 104. Such a force need only overcome the magnetic force between the first and second magnetic elements 116, 132.

In some embodiments, the magnetically coupled fan assembly 100 may be an attachment to a separate computer (not shown). In some embodiments, the fan blade assembly 104 of the magnetically coupled fan assembly 100 may be coupled to a fan attachment unit included within a computer chassis of a computer. Such a fan attachment unit may function the same as the base assembly 108 described above but may be incorporated as an integral component of the computer chassis. For example, in such embodiments, the printed circuit board 136 may be disposed on a component of a computer, rather than the support structure 152 shown in FIG. 4. The magnetically coupled fan assembly 100 may be configured such that the magnetically coupled fan assembly 100 is positioned adjacent to a graphics card, or another computer component, such that air forced by the magnetically coupled fan assembly 100 may cool such graphics card or computer component.

In some embodiments, the base assembly 108 may further include a power supply configured to provide power to the fan assembly 100. In some embodiments, the power supply may be an external component, such as the computer to which the fan assembly 100 is attached.

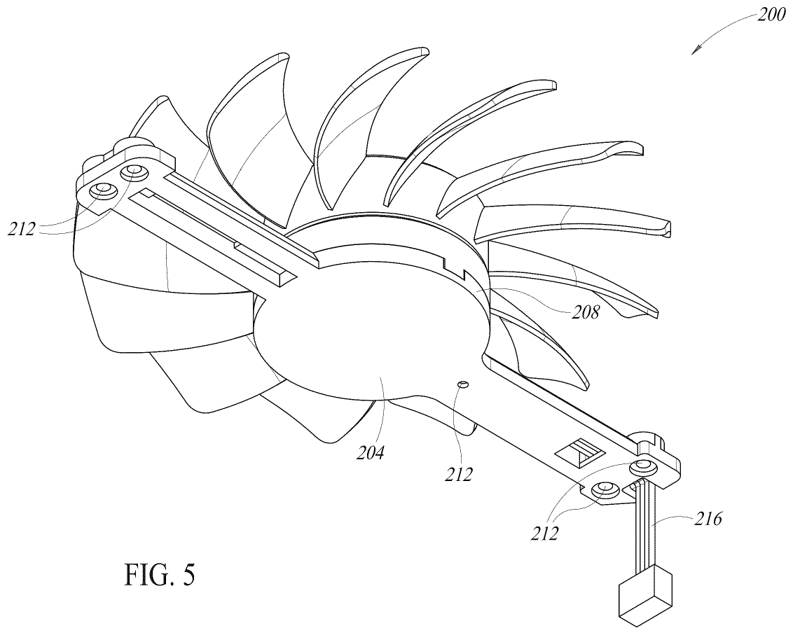

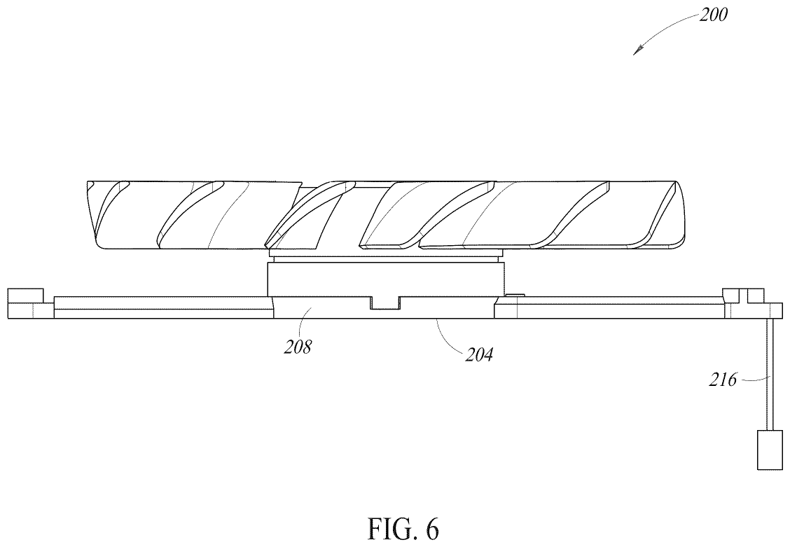

FIGS. 5 and 6 show an embodiment of a magnetically coupled fan assembly 200 having a similar configuration to the magnetically coupled fan assembly 100 but including an extended support structure 204 of a base assembly 208. The extended support structure 204 may permit multiple fastening points 212 to an external computer chassis or an external fan chassis. The extended support structure may also provide a pathway for at least one connection wire 216. The connection wire may connect a printed circuit board within the base assembly 208 and an external controller.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A fan assembly, comprising:
a fan blade assembly including a plurality of fan blades, a first magnetic element, and a connector, the plurality of fan blades extending from a blade center; and
a base assembly including a printed circuit board and a second magnetic element, the printed circuit board including at least one continuous circular contact ring on a first face of the printed circuit board,
wherein the first magnetic element and the second magnetic element are each configured to be removably coupled to one another,
wherein the connector is in contact with the at least one continuous circular contact ring of the printed circuit board when the first magnetic element and second magnetic element are removably coupled,
wherein the fan blade assembly is configured to selectively rotate about the blade center when the first magnetic element and the second magnetic element are removably coupled to one another, and
wherein the base assembly is configured to remain rotatably stationary when the fan blade assembly is rotating.

2. The fan assembly of claim 1, wherein the connector is in contact with the at least one continuous circular contact ring of the printed circuit board when the fan blade assembly is in any rotational position relative to the base assembly.

3. The fan assembly of claim 1, wherein the first magnetic element and the second magnetic element are each configured to remain rotatably coupled as the fan blade assembly rotates relative to the base assembly.

4. The fan assembly of claim 1, wherein the first magnetic element is configured to be decoupled from the second magnetic element in response to the application of a force on the fan blade assembly in a direction away from the second magnetic element.

5. The fan assembly of claim 1, wherein the first magnetic element is concentric with the plurality of fan blades and the second magnetic element is concentric with the at least one continuous circular contact ring.

6. The fan assembly of claim 1, wherein the connector includes one or more pins, and wherein each pin of the one or more pins is in contact with a respective continuous circular contact ring of the one or more continuous circular contact rings when the first magnetic element is removably coupled to the second magnetic element.

7. The fan assembly of claim 1, wherein the fan blade assembly further includes a DC motor configured to rotate the plurality of fan blades about the blade center.

8. The fan assembly of claim 7, wherein the DC motor is controlled by a computer electronically coupled to the fan assembly.

9. The fan assembly of claim 1, wherein the fan blade assembly is configured to force air over a graphics card of a computer.

10. A computer component cooling assembly, comprising:
a fan blade assembly including a plurality of fan blades, a first magnetic element, and a connector, the plurality of fan blades extending from a blade center; and
a computer chassis including a fan attachment unit, the fan attachment unit including a printed circuit board and a second magnetic element, the printed circuit board including at least one continuous circular contact ring on a first face of the printed circuit board;
wherein the first magnetic element and the second magnetic element are each configured to be removably coupled to one another,
wherein the connector is in contact with the at least one continuous circular contact ring of the printed circuit board when the first magnetic element and second magnetic element are removably coupled,
wherein the fan blade assembly is configured to selectively rotate about the blade center when the first magnetic element and the second magnetic element are removably coupled to one another, and
wherein the fan attachment unit is configured to remain rotatably stationary when the fan blade assembly is rotating.

11. The computer component cooling assembly of claim 10, wherein the connector is in contact with the at least one continuous circular contact ring of the printed circuit board when the fan blade assembly is in any rotational position relative to the fan attachment unit.

12. The computer component cooling assembly of claim 10, wherein the first magnetic element and the second magnetic element are each configured to remain rotatably coupled as the fan blade assembly rotates relative to the fan attachment unit.

13. The computer component cooling assembly of claim 10, wherein the first magnetic element is configured to be decoupled from the second magnetic element by a applying a force to the fan blade assembly in a direction away from the second magnetic element.

14. The computer component cooling assembly of claim 10, wherein the first magnetic element is concentric with the plurality of fan blades and the second magnetic element is concentric with the at least one continuous circular contact ring.

15. The computer component cooling assembly of claim 10, wherein the connector includes one or more pins, and wherein each pin of the one or more pins is in contact with a respective continuous circular contact ring of the one or more continuous circular contact rings when the first magnetic element is removably coupled to the second magnetic element.

16. The computer component cooling assembly of claim 10, wherein the fan blade assembly further includes a DC motor configured to rotate the plurality of fan blades about the blade center.

17. The computer component cooling assembly of claim 16, wherein the DC motor is controlled by a computer housed in the computer chassis.

18. The computer component cooling assembly of claim 10, wherein the fan blade assembly is configured to force air over a component of a computer housed in the computer chassis.
